(19) United States
(12) Patent Application Publication
(10) Pub. No.: US 2023/0386982 A1
(43) Pub. Date: Nov. 30, 2023

(54) Charging Base Lead Frame, Charging Base Lead Frame Assembly and Charging Base

(71) Applicants: Tyco Electronics (Suzhou) Ltd., Suzhou City (CN); Tyco Electronics Technology (SIP) Ltd., Suzhou (CN); Tyco Electronics (Shanghai) Co., Ltd., Shanghai (CN)

(72) Inventors: Fangyue (Jason) Zhu, Shanghai (CN); Jinshun (Jet) Wang, Suzhou (CN); Han Wu, Suzhou (CN)

(73) Assignees: Tyco Electronics (Suzhou) Ltd., Suzhou City (CN); Tyco Electronics Technology (SIP) Ltd., Suzhou (CN); Tyco Electronics (Shanghai) Co., Ltd., Shanghai (CN)

(21) Appl. No.: 18/325,483

(22) Filed: May 30, 2023

(30) Foreign Application Priority Data
May 30, 2022 (CN) 202221318765.6

(51) Int. Cl. H01L 23/495; H01L 23/34

(52) U.S. Cl. CPC H01L 23/49551; H01L 23/34; H01L 23/49558; H01L 23/49517

(57) ABSTRACT

A charging base lead frame includes a frame body having a receiving slot and a plurality of leads fixed to the frame body. The leads include a first lead for electrical connection to a terminal of a charging base. The first lead includes a lead body fixed to the frame body, a pair of elastic cantilevers connected to the lead body and suspended in the receiving slot for clamping the terminal, and a pair of bridging arms respectively connecting a pair of fixed ends of the pair of elastic cantilevers to the lead body. At least a portion of the fixed ends of each of the elastic cantilevers is wrapped in the frame body.

### CROSS-REFERENCE TO RELATED APPLICATION

This application claims the benefit of the filing date under 35 U.S.C. § 119(a)-(d) of Chinese Patent Application No. 202221318765.6, filed on May 30, 2022.

### FIELD OF THE INVENTION

This present invention relates to a charging base lead frame, a charging base lead frame assembly comprising the charging base lead frame, and a charging base including the charging base lead frame or the charging base lead frame assembly.

### BACKGROUND

In the prior art, the charging base on new energy vehicles typically includes a housing, a charging terminal, a signal terminal, a temperature sensor, and a lead frame. The charging terminal and signal terminal are installed in the housing. The temperature sensor is installed on the lead frame. The lead frame includes a frame body and multiple leads fixed to the frame body. The signal terminal and temperature sensor are electrically connected to the corresponding leads in the lead frame. The lead electrically connected to the signal terminal usually includes a lead body, a pair of elastic cantilevers, and a pair of bridging arms. The pair of bridging arms connect the fixed ends of the pair of elastic cantilevers to the lead body. The signal terminal is clamped between the pair of elastic cantilevers of the lead wire.

In the prior art, the pair of elastic cantilevers and the pair of bridging arms on the lead electrically connected to the signal terminal are exposed from the outside of the frame body. Therefore, when mating the pair of elastic cantilevers with the signal terminal, the roots (fixed ends) of the elastic cantilevers are prone to folding backwards. In the prior art, in order to prevent the root of the elastic cantilever from folding backwards, the width of the bridging arm connected to the root of the elastic cantilever is usually increased. Although increasing the width of the bridging arm will enhance the strength of the root of the elastic cantilever, it will reduce the effective length and elasticity of the elastic cantilever.

### SUMMARY

A charging base lead frame includes a frame body having a receiving slot and a plurality of leads fixed to the frame body. The leads include a first lead for electrical connection to a terminal of a charging base. The first lead includes a lead body fixed to the frame body, a pair of elastic cantilevers connected to the lead body and suspended in the receiving slot for clamping the terminal, and a pair of bridging arms respectively connecting a pair of fixed ends of the pair of elastic cantilevers to the lead body. At least a portion of the fixed ends of each of the elastic cantilevers is wrapped in the frame body.

### BRIEF DESCRIPTION OF THE DRAWINGS

Features of the present invention will become more apparent by describing in detail exemplary embodiments thereof with reference to the accompanying drawings, in which:

FIG. 1 is a perspective view of a charging base lead frame according to an embodiment;

FIG. 2 is a perspective view of a plurality of leads in the charging base lead frame according to an embodiment;

FIG. 3 is a perspective view of a first lead of the plurality of leads;

FIG. 4 is an enlarged perspective view from an upper side of the first lead;

FIG. 5 is an enlarged perspective view of a bottom of the first lead;

FIG. 6 is a perspective view of the first lead and a matching terminal;

FIG. 7 is a perspective view of a charging base lead frame according to another embodiment, where only one first lead is shown;

FIG. 8 is a perspective view of a pair of elastic cantilevers between the first lead wire inserted into the charging base lead frame; and

FIG. 9 is a plan view of the charging base lead frame and a plurality of terminals according to an embodiment.

### DETAILED DESCRIPTION OF EXEMPLARY EMBODIMENTS

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

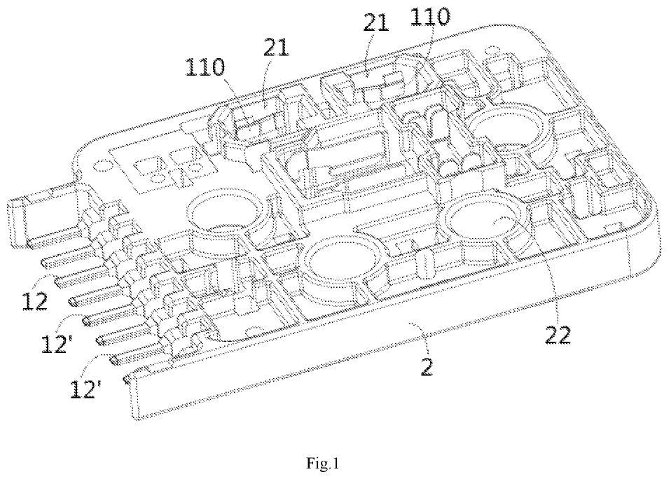

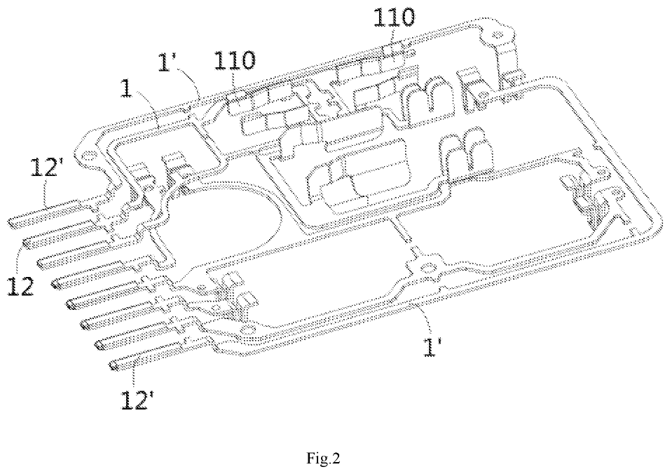

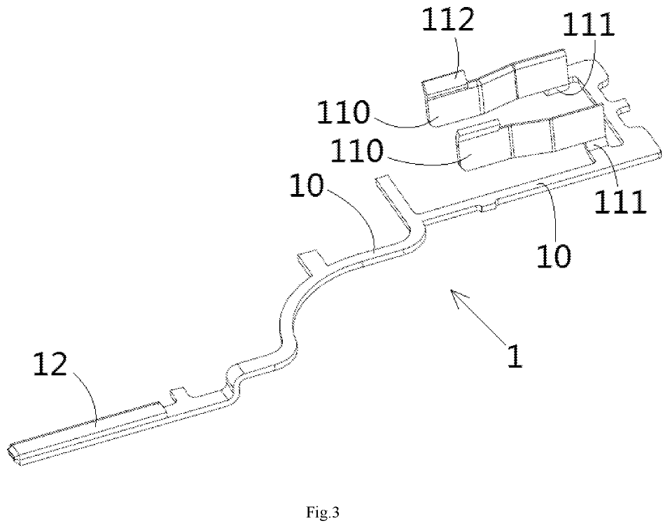

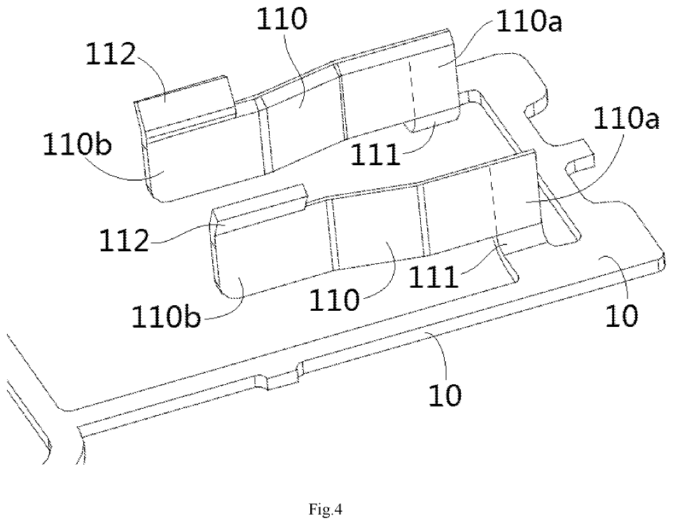

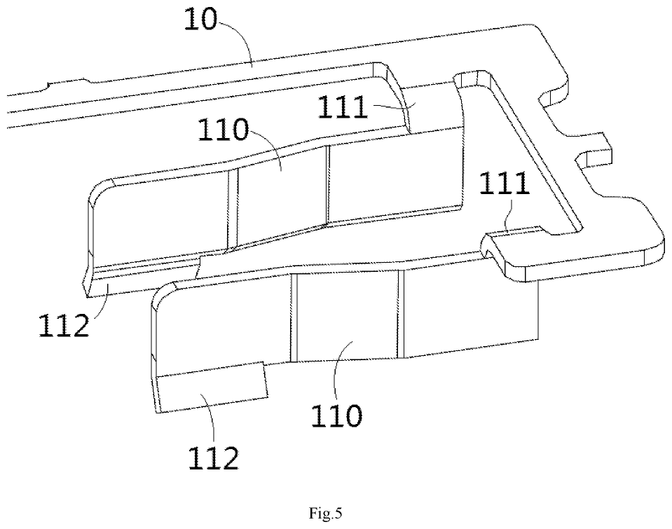

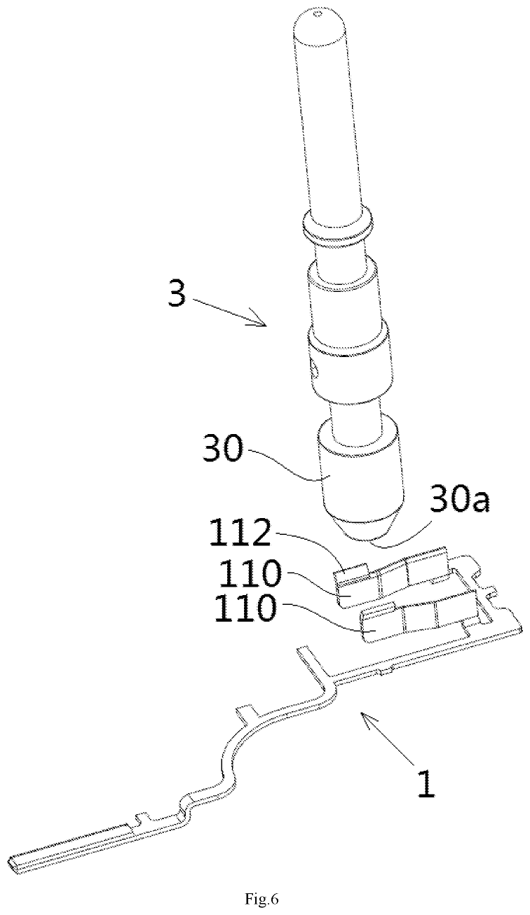

FIG. 1 shows an illustrative perspective view of a charging base lead frame according to an exemplary embodiment of the present invention. FIG. 2 shows an illustrative perspective view of multiple leads 1, 1′ in the charging base lead frame according to an exemplary embodiment of the present invention. FIG. 3 shows an illustrative perspective view of the first lead 1 among multiple leads 1 and 1′ in the charging base lead frame according to an exemplary embodiment of the present invention. FIG. 4 shows an illustrative partially enlarged view of the first lead 1 shown in FIG. 3 when viewed from the upper side. FIG. 5 shows an illustrative partially enlarged view of the first lead 1 shown in FIG. 3, viewed from the bottom. FIG. 6 shows an illustrative perspective view of the first lead 1 mated with terminal 3 as shown in FIG. 3.

The charging base lead frame includes: a frame body 2 and a plurality of leads 1, 1′. A receiving slot 21 is formed on the frame body 2. Multiple leads 1 and 1′, shown in detail in FIG. 2, are fixed to frame body 2.

The multiple leads 1, 1′ include a first lead 1 for electrical connection to a terminal 3 of the charging base. The first lead 1, as shown in FIG. 3, a lead body 10, a pair of elastic cantilevers 110, and a pair of bridging arms 111. The lead body 10 is fixed to the frame body 2. The pair of elastic cantilevers 110 are connected to the lead body 10 and suspended in the receiving slot 21 for clamping the terminal 3. The pair of bridging arms 111 is used to connect the fixed ends 110a, shown in FIG. 4, of the pair of elastic cantilevers 110 to the lead body 10 respectively.

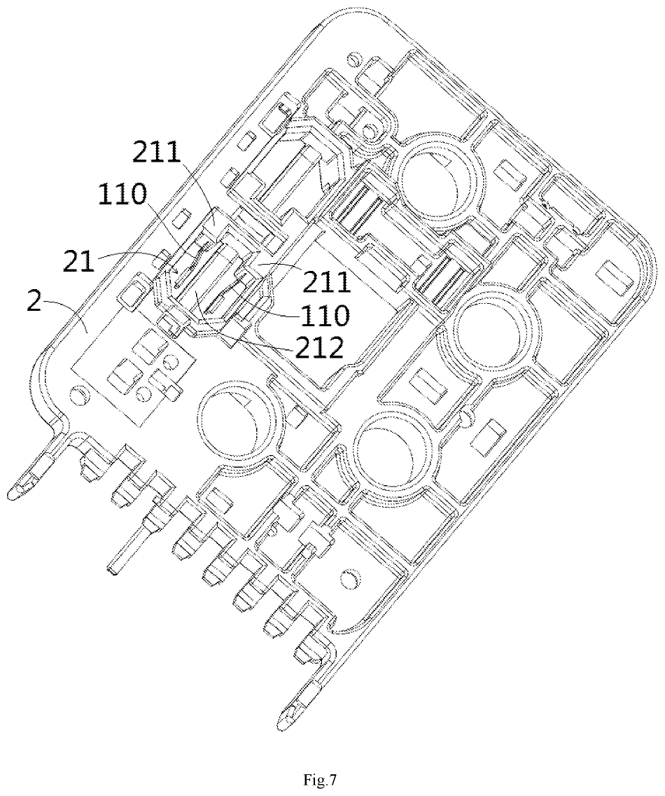

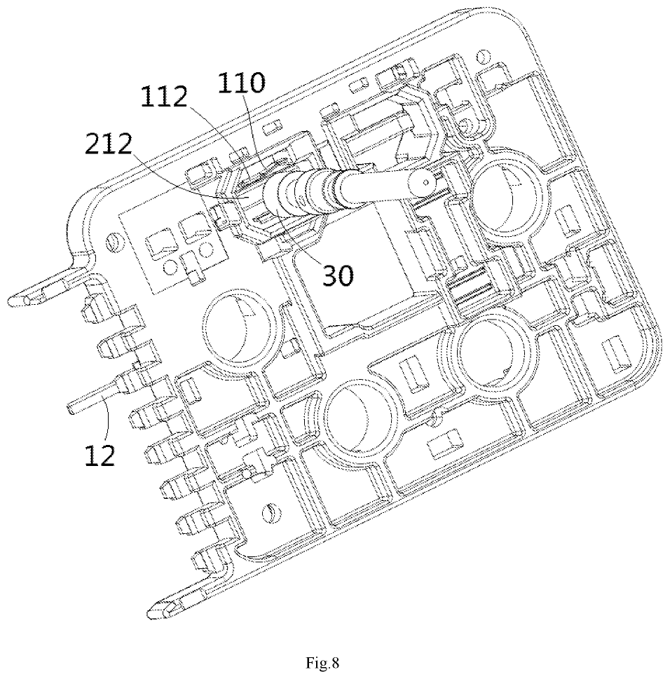

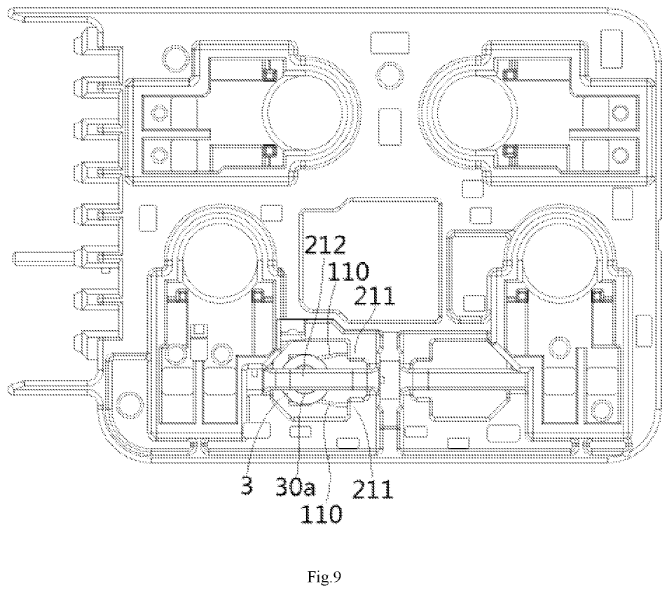

FIG. 7 shows an illustrative perspective view of a charging base lead frame according to an exemplary embodiment of the present invention, where only one first lead 1 is shown. FIG. 8 shows an illustrative view of a pair of elastic cantilevers 110 between the first lead 1 inserted into the charging base lead frame. FIG. 9 shows a plan view of the charging base lead frame and terminal 3 viewed from the rear according to an exemplary embodiment of the present invention.

As shown in FIGS. 1 and 7 to 9, in an exemplary embodiment of the present invention, at least a portion of the bridging arm 111 and/or at least a portion of the fixed end 110a of the elastic cantilever 110 are wrapped in the frame body 2. In this way, the strength of the root of the elastic cantilever 110 can be enhanced, and it can effectively prevent the root of the elastic cantilever 110 from folding backwards when mated with the terminal 3. In the illustrated embodiments, all of the bridging arm 111 and all of the fixed end 110a of the elastic cantilever 110 are wrapped in the frame body 2. The rest part of the elastic cantilever 110 except for the fixed end 110a is exposed from the frame body 2 and suspended in the receiving slot 21.

However, the present invention is not limited to the illustrated embodiments. For example, in another exemplary embodiment of the present invention, a portion of the bridging arm 111 and/or a portion of the fixed end 110a of the elastic cantilever 110 are wrapped in the frame body 2. The part of the fixed end 110a of the elastic cantilever 110 and the part of the bridging arm 111 that are not wrapped in the frame body 2 are suspended in the receiving slot 21.

As shown in FIGS. 3 and 4, the bridging arm 111 is located at one side of the width direction of the elastic cantilever 110 and connected to the side edge of the fixed end 110a of the elastic cantilever 110. The width direction of bridging arm 111 is parallel to the length direction of elastic cantilever 110, and the width of bridging arm 111 is smaller than the width of elastic cantilever 110. The width of the bridging arm 111 can be 10% to 60% of the width of the elastic cantilever 110, or the width of the bridging arm 111 can be 20% to 50% of the width of the elastic cantilever 110. In this way, the effective length and elasticity of the elastic cantilever 110 can be increased by reducing the width of the bridging arm 111.

As shown in FIG. 4, one side of the width direction of the bridging arm 111 is flush with the end side of the fixed end 110a of the elastic cantilever 110. At least a portion of the bridging arm 111 and at least a portion of the fixed end 110a of the elastic cantilever 110 are wrapped in the frame body 2. At least a portion of the bridging arm 111 is bent relative to the surface of the lead body 10. For example, the bridging arm 111 is roughly bent 90 degrees relative to the surface of the lead body 10, so that the surface of the elastic cantilever 110 is roughly perpendicular to the surface of the lead body 10.

The frame body 2 has a protruding portion 211, shown in FIG. 7, protruding into the receiving slot 21, and at least a portion of the bridging arm 111 and at least a portion of the fixed end 110a of the elastic cantilever 110 are wrapped in the protruding portion 211. In the illustrated embodiment, the protruding portion 211 is located at the corner of the receiving slot 21 and connected to the adjacent two sides of the receiving slot 21.

The frame body 2 has a front and a back, and the frame body 2 has a limit beam 212 located on its back and bridging between two sides of the receiving slot 21, as shown in FIGS. 7 to 9. The limit beam 212 is located between the pair of elastic cantilevers 110 and extends along the length direction of the elastic cantilevers 110. When the terminal 3 is installed on the charging base lead frame, one end 30 of the terminal 3 is inserted between the free ends 110b of the pair of elastic cantilevers 110, as schematically shown in FIG. 6, and the end face 30a of one end of the terminal 3 is against the limit beam 212.

As shown in FIG. 1, a through hole 22 is also formed on the frame body 2 that allows the charging terminal to pass through.

The multiple leads 1, 1′ also include a second lead 1′, shown in FIG. 2, for electrical connection to the temperature sensor of the charging base. The pins 12 and 12′ of the first lead 1 and the second lead 1′ are exposed from one side of the frame body 2 and arranged in a row. The first lead 1 further includes a pair of guide wings 112. The pair of guide wings 112 are respectively connected to one sides of the free ends 110b of the pair of elastic cantilevers 110. The pair of guide wings 112 are flared outward in an octagonal shape to guide the end 30 of the terminal 3 to be inserted between the free ends 110b of the pair of elastic cantilevers 110.

Each of the multiple leads 1 and 1′ is an integrated stamping molded part, and the frame body 2 and the multiple leads 1 and 1′ are formed into an integrated injection molded part, so that the injection molded frame body 2 to directly engage with multiple leads 1 and 1′. This can reduce manufacturing costs.

In an embodiment, a charging base lead frame assembly is also disclosed. The charging base lead frame assembly includes: the above charging base lead frame and a temperature sensor. The temperature sensor is installed on the frame body 2 of the charging base lead frame to detect the temperature of the charging terminal of the charging base. The temperature sensor is electrically connected to the second lead 1′ in the charging base lead frame.

In an embodiment, a charging base is also disclosed. The charging base includes a housing, the above charging base lead frame, and a terminal 3. The charging base lead frame is installed in the housing. The terminal 3 is installed in the housing and clamped between the pair of elastic cantilevers 110 of the first lead 1 of the charging base lead frame.

In an embodiment, a charging base is also disclosed. The charging base includes a housing, the above charging base lead frame assembly, and a terminal 3. The charging base lead frame is installed in the housing. The terminal 3 is installed in the housing and clamped between the pair of elastic cantilevers 110 of the first lead 1 of the charging base lead frame. In an embodiment, the aforementioned terminal 3 can be the signal terminal of the charging station. The charging base also includes a charging terminal. The charging terminal is installed in the housing and passes through the charging base lead frame through the through hole 22 on the frame body 2.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A charging base lead frame, comprising:
a frame body having a receiving slot; and
a plurality of leads fixed to the frame body and including a first lead for electrical connection to a terminal of a charging base, the first lead includes:
a lead body fixed to the frame body;
a pair of elastic cantilevers connected to the lead body and suspended in the receiving slot for clamping the terminal; and
a pair of bridging arms respectively connecting a pair of fixed ends of the pair of elastic cantilevers to the lead body, at least a portion of the fixed ends of each of the elastic cantilevers is wrapped in the frame body.

2. The charging base lead frame according to claim 1, wherein a portion of each of the bridging arms is wrapped in the frame body.

3. The charging base lead frame according to claim 2, wherein a part of the fixed ends of each of the elastic cantilevers and a part of each of the bridging arms that is not wrapped in the frame body is suspended in the receiving slot.

4. The charging base lead frame according to claim 1, wherein all of the bridging arms and all of the fixed ends of the elastic cantilevers are wrapped in the frame body.

5. The charging base lead frame according to claim 4, wherein a rest of each of the elastic cantilevers other than the fixed ends is exposed from the frame body and suspended in the receiving slot.

6. The charging base lead frame according to claim 1, wherein each of the bridging arms is located at one side in a width direction of one of the elastic cantilevers and is connected to a side edge of the fixed end of the one of the elastic cantilevers.

7. The charging base lead frame according to claim 6, wherein the width direction of the bridging arms is parallel to a length direction of the elastic cantilevers, and a width of each of the bridging arms is smaller than a width of each of the elastic cantilevers.

8. The charging base lead frame according to claim 7, wherein the width of each of the bridging arms is 10% to 60% of the width of each of the elastic cantilevers, or the width of each of the bridging arms is 20% to 50% of the width of each of the elastic cantilevers.

9. The charging base lead frame according to claim 6, wherein the one side in the width direction of each of the bridging arms is flush with an end side of the fixed end of one of the elastic cantilevers, and a portion of each of the bridging arms is wrapped in the frame body.

10. The charging base lead frame according to claim 6, wherein at least a part of each of the bridging arms is bent relative to a surface of the lead body, a surface of each of the elastic cantilevers is roughly perpendicular to the surface of the lead body.

11. The charging base lead frame according to claim 1, wherein the frame body has a protruding part protruding into the receiving slot, at least a portion of each of the bridging arms and at least a portion of each of the fixed ends of the elastic cantilevers are wrapped in the protruding part.

12. The charging base lead frame according to claim 1, wherein the frame body has a front and a back, the frame body has a limit beam located on the back and bridging between a pair of sides of the receiving slot, the limit beam is located between the elastic cantilevers and extends along a length direction of the elastic cantilevers, an end of the terminal is inserted between a pair of free ends of the pair of elastic cantilevers, and an end face of the end of the terminal is against the limit beam.

13. The charging base lead frame according to claim 1, wherein a through hole is formed in the frame body to allow the terminal to pass through.

14. The charging base lead frame according to claim 1, wherein the plurality of leads include a second lead electrically connecting to a temperature sensor of the charging base, a plurality of pins of the first lead and the second lead are exposed from a side of the frame body and arranged in a row.

15. The charging base lead frame according to claim 1, wherein the first lead includes a pair of guide wings respectively connected to a pair of sides of a pair of free ends of the elastic cantilevers, the pair of guide wings are flared outward in an octagonal shape to guide an end of the terminal to be inserted between the free ends of the pair of elastic cantilevers.

16. The charging base lead frame according to claim 1, wherein each of the plurality of leads is an integrated stamping molded part, the frame body and the plurality of leads are formed into an integrated injection molded part and the frame body is directly bonded to the plurality of leads.

17. A charging base lead frame assembly, comprising:
a charging base lead frame including a frame body having a receiving slot and a plurality of leads fixed to the frame body and including a first lead for electrical connection to a terminal of a charging base and a second lead, the first lead includes a lead body fixed to the frame body, a pair of elastic cantilevers connected to the lead body and suspended in the receiving slot for clamping the terminal, and a pair of bridging arms respectively connecting a pair of fixed ends of the pair of elastic cantilevers to the lead body, at least a portion of the fixed ends of each of the elastic cantilevers is wrapped in the frame body; and
a temperature sensor installed on the frame body to detect a temperature of the terminal of the charging base, the temperature sensor is electrically connected to the second lead.

18. A charging base, comprising:
a housing;
a charging base lead frame installed in the housing, the charging base lead frame including a frame body having a receiving slot and a plurality of leads fixed to the frame body and including a first lead, the first lead includes a lead body fixed to the frame body, a pair of elastic cantilevers connected to the lead body and suspended in the receiving slot for clamping the terminal, and a pair of bridging arms respectively connecting a pair of fixed ends of the pair of elastic cantilevers to the lead body, at least a portion of the fixed ends of each of the elastic cantilevers is wrapped in the frame body; and
a terminal installed in the housing and clamped between the pair of elastic cantilevers of the first lead.

19. The charging base of claim 18, wherein the terminal is a signal terminal.

20. The charging base of claim 18, further comprising a charging terminal installed in the housing and passing through the charging base lead frame.
